(19) United States
(12) Patent Application Publication
(10) Pub. No.: US 2026/0249598 A1
(43) Pub. Date: Aug. 27, 2026

(54) COMPOSITE SUBSTRATE AND MANUFACTURING METHOD THEREOF

(71) Applicant: AZOTEK CO., LTD., Taoyuan City (TW)

(72) Inventor: Hung-Jung LEE, Taoyuan City (TW)

(21) Appl. No.: 19/291,638

(22) Filed: Aug. 6, 2025

(30) Foreign Application Priority Data
Feb. 24, 2025 (TW) 114106796

(51) Int. Cl. B32B 27/32; B32B 7/12; B32B 27/08; B32B 27/20; B32B 37/06; B32B 37/10; B32B 37/12

(52) U.S. Cl. CPC B32B 27/322; B32B 7/12; B32B 27/08; B32B 27/20; B32B 37/06; B32B 37/10; B32B 2037/1253; B32B 2250/03; B32B 2250/40; B32B 2255/10; B32B 2264/102; B32B 2305/55; B32B 2327/18

(57) ABSTRACT

The present disclosure provides a composite substrate and a manufacturing method thereof. The composite substrate includes a first fluoropolymer layer, a liquid crystal polymer layer, and a second fluoropolymer layer. The liquid crystal polymer layer is bonded to an upper surface of the first fluoropolymer layer. The second fluoropolymer layer is bonded to an upper surface of the liquid crystal polymer layer. The first fluoropolymer layer and the second fluoropolymer layer independently include: 30 parts by weight to 50 parts by weight of a fluoropolymer, 1 part by weight to 5 parts by weight of a dispersant, 1 part by weight to 10 parts by weight of a plurality of inorganic particles, and 1 part by weight to 5 parts by weight of a macromolecule resin, in which the macromolecule resin is different from the fluoropolymer.

### CROSS-REFERENCE TO RELATED APPLICATION

This application claims priority to Taiwan Application Serial Number 114106796, filed Feb. 24, 2025, which is herein incorporated by reference.

### BACKGROUND

### Field of Invention

The present disclosure relates to a composite substrate and a manufacturing method thereof.

### Description of Related Art

With the development of communication technology, various printed circuit boards have been developed to increase signal transmission speed and to reduce production costs. Printed circuit boards are indispensable components in electronic products. With the increase in demand for consumer electronic products, the demand for printed circuit boards is also increasing. For example, flexible printed circuit boards are flexible and have been widely used in communication products and consumer electronic products. However, in order to further meet the requirements of communication technology for the dielectric constant, loss factor, etc., of circuit boards, it is necessary to provide a new substrate and its manufacturing method.

### SUMMARY

The present disclosure provides a composite substrate including a first fluoropolymer layer, a liquid crystal polymer layer, and a second fluoropolymer layer. The liquid crystal polymer layer is bonded to an upper surface of the first fluoropolymer layer. The second fluoropolymer layer is bonded to an upper surface of the liquid crystal polymer layer. The first fluoropolymer layer and the second fluoropolymer layer independently include: 30 parts by weight to 50 parts by weight of a fluoropolymer, 1 part by weight to 5 parts by weight of a dispersant, 1 part by weight to 10 parts by weight of a plurality of inorganic particles, and 1 part by weight to 5 parts by weight of a macromolecule resin, in which the macromolecule resin is different from the fluoropolymer.

In some embodiments, the fluoropolymer includes polytetrafluoroethylene (PTFE), ethylene-tetrafluoroethylene copolymer (ETFE copolymer), tetrafluoroethylene-hexafluoropropene copolymer, tetrafluoroethylene-perfluoroalkyl vinyl ether copolymer, polychlorotrifluoroethylene (PCTFE), ethylene-trifluorochloroethylene copolymer (ECTFE copolymer), trifluorochloroethylene-tetrafluoroethylene copolymer, polyvinylidene difluoride (PVDF), tetrafluoroethylene-hexafluoropropene-difluoroethylene copolymer, tetrafluoroethylene-perfluoroalkoxy vinyl ether copolymer, or combinations thereof.

In some embodiments, the inorganic particles include titanium dioxide, silicon dioxide, aluminum oxide, zirconium dioxide, magnesium oxide, calcium oxide, talc, aluminium hydroxide, magnesium hydroxide, barium sulfate, calcium carbonate, potassium titanate, clay, or combinations thereof.

In some embodiments, the dispersant includes ethyl acetate, butyl acetate, ethylene glycol ethyl ether acetate, phthalate, propylene glycol methyl ether acetate, urethane acrylate, tripropylene glycol diacrylate, 1,6-hexanediol diacrylate, propylene glycol monomethyl ether acetate, ethylene glycol methyl ether acetate, 2-methoxyethyl acetate, ethyl acrylate, fatty acid polyethylene glycol ester, vinyl formate, methyl acrylic ester, or combinations thereof.

In some embodiments, the macromolecule resin includes poly (acrylic acid) (PAA), polyimide, a liquid crystal polymer, a cyclic olefin polymer, a cyclic olefin copolymer, a styrene-butadiene copolymer, a styrene-ethylene copolymer, a styrene-propylene copolymer, a styrene-butylene copolymer, a polyester, a polyolefin, polyphenylene ether, polyphenylene sulfide, styrene, polycarbonate, polyarylate, maleimide resin, polysulfone, polyarylsulfone, polyaryletherketone, epoxy resin, polyvinyl acetate, polyaryl amide, polyetheretherketone (PEEK), poly (ether sulfone) (PES), polyphenylene oxide (PPO), polyoxymethylene, polyetherimide, polysiloxane, or combinations thereof.

The present disclosure provides a method for manufacturing a composite substrate, and the method includes the following operations. A first fluoropolymer layer, a liquid crystal polymer layer, and a second fluoropolymer layer are stacked in a bottom-to-top sequence. The first fluoropolymer layer and the second fluoropolymer layer independently include: 30 parts by weight to 50 parts by weight of a fluoropolymer, 1 part by weight to 5 parts by weight of a dispersant, 1 part by weight to 10 parts by weight of a plurality of inorganic particles, and 1 part by weight to 5 parts by weight of a macromolecule resin, in which the macromolecule resin is different from the fluoropolymer. A heating process is performed to bond the first fluoropolymer layer, the liquid crystal polymer layer, and the second fluoropolymer layer, in which a temperature of the heating process is 200° C. to 400° C. or a glass transition temperature of the fluoropolymer to a melting point of the fluoropolymer +40° C.

In some embodiments, the first fluoropolymer layer and the second fluoropolymer layer further include 30 parts by weight to 60 parts by weight of a solvent and respectively a dispersion liquid layer, and the liquid crystal polymer layer is a solid film or an adhesive layer.

In some embodiments, the solvent includes N-methyl-2-pyrrolidone (NMP), methyl ethyl ketone (MEK), N,N-dimethylacetamide (DMAC), or combinations thereof.

In some embodiments, the first fluoropolymer layer, the second fluoropolymer layer, and the liquid crystal polymer layer are respectively a solid film.

In some embodiments, the method further includes: when performing the heating process, placing the first fluoropolymer layer, the liquid crystal polymer layer, and the second fluoropolymer layer in a nitrogen gas oven or an infrared oven.

In some embodiments, the method further includes: when performing the heating process, performing a pressing process, in which the pressing process has a pressure of 1 kg/cm² to 100 kg/cm².

In some embodiments, the heating process has a heating time of 1 minute to 300 minutes.

In some embodiments, the method further includes hot-pressing the composite substrate and a metal substrate.

In some embodiments, the method further includes the following operations. The first fluoropolymer layer, the liquid crystal polymer layer, and the second fluoropolymer layer are stacked in the bottom-to-top sequence on a metal substrate, and the heating process is performed to bond the first fluoropolymer layer and the metal substrate.

In some embodiments, the method further includes the following operations. Before the first fluoropolymer layer, the liquid crystal polymer layer, and the second fluoropolymer layer are stacked in the bottom-to-top sequence, a first liquid crystal polymer adhesive layer is coated to cover an upper surface of the first fluoropolymer layer. A second liquid crystal polymer adhesive layer is coated to cover a lower surface of the second fluoropolymer layer. The first liquid crystal polymer adhesive layer and the second liquid crystal polymer adhesive layer are cured to respectively form a first portion and a second portion of the liquid crystal polymer layer.

In some embodiments, the method further includes the following operations. Before the first fluoropolymer layer, the liquid crystal polymer layer, and the second fluoropolymer layer are stacked in the bottom-to-top sequence, a liquid crystal polymer adhesive layer is coated to cover a lower surface of the second fluoropolymer layer. The liquid crystal polymer adhesive layer is cured to form the liquid crystal polymer layer.

### BRIEF DESCRIPTION OF THE DRAWINGS

The present disclosure can be more fully understood by reading the following detailed description of the embodiments, with reference made to the accompanying drawings.

FIG. 1 is a schematic cross-sectional view of a composite substrate according to various embodiments of the present disclosure.

FIG. 2 is a flow chart of a method for manufacturing a composite substrate according to various embodiments of the present disclosure.

FIG. 3, FIG. 4, FIG. 5, FIG. 6, FIG. 7, FIG. 8, FIG. 9, FIG. 10, FIG. 11, and FIG. 12 are respectively schematic cross-sectional views of intermediate stages of manufacturing a composite substrate according to various embodiments of the present disclosure.

FIG. 13 is a schematic view of manufacturing a composite substrate of Experimental Example 1.

FIG. 14 is a schematic cross-sectional view of a composite substrate of Experimental Example 2.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The present disclosure provides a composite substrate and a method for manufacturing the same. The composite substrate includes two fluoropolymer layers and a liquid crystal polymer layer, in which the liquid crystal polymer layer is sandwiched between the fluoropolymer layers. The surfaces of the fluoropolymer layer and the liquid crystal polymer layer can be bonded to each other by a heating process without surface treatment and/or without adhesive layer coating, and the peel strength between the interfaces can be, for example, greater than or equal to 1 kgf/cm. The composite substrate can be used as a high-frequency and high-speed substrate, a substrate for a flexible printed circuit board, an interposer for a tape ball grid array (TBGA), an interposer for a chip scale package (CSP), or a carrier film/adhesive film for tape-automated bonding technology. The composite substrate of the present disclosure can have a low dielectric constant, a low loss factor, a low thermal expansion coefficient, a low water absorption rate, and good bonding strength.

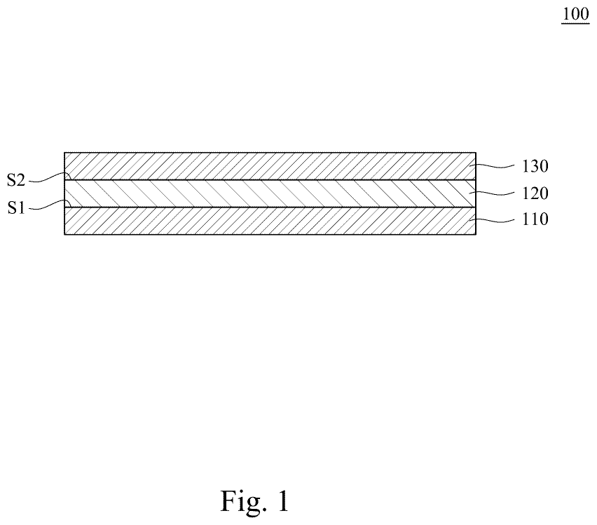

The present disclosure provides a composite substrate 100. FIG. 1 is a schematic cross-sectional view of the composite substrate 100 according to various embodiments of the present disclosure. The composite substrate 100 includes a first fluoropolymer layer 110, a liquid crystal polymer layer 120, and a second fluoropolymer layer 130. The liquid crystal polymer layer 120 is bonded to an upper surface S1 of the first fluoropolymer layer 110. The second fluoropolymer layer 130 is bonded to an upper surface S2 of the liquid crystal polymer layer 120. In some embodiments, the thicknesses of the first fluoropolymer layer 110, the liquid crystal polymer layer 120, and the second fluoropolymer layer 130 are independently 1 μm to 150 μm, such as 1, 5, 10, 20, 30, 40, 50, 60, 70, 80, 90, 100, 110, 120, 130, 140, or 150 μm.

In some embodiments, before the first fluoropolymer layer 110, the liquid crystal polymer layer 120, and the second fluoropolymer layer 130 are bonded, the surfaces of the first fluoropolymer layer 110, the liquid crystal polymer layer 120, and the second fluoropolymer layer 130 do not need to be surface-treated. In some embodiments, it is not necessary to set any adhesive layer (such as a low dielectric adhesive) between the first fluoropolymer layer 110, the liquid crystal polymer layer 120, and the second fluoropolymer layer 130. Therefore, it can be seen that the fluoropolymer at least brings the effect of being directly heat-bonded with the liquid crystal polymer layer 120. In addition, when at least one metal substrate (such as copper foil, aluminum foil, gold foil, or combinations thereof) is further provided on the lower surface of the first fluoropolymer layer 110 and/or the upper surface of the second fluoropolymer layer 130, the surfaces of the first fluoropolymer layer 110 and the second fluoropolymer layer 130 do not need to be surface-treated, nor is it necessary to provide any adhesive layer (such as low dielectric glue) between the metal substrate and the fluoropolymer layer. The interface between the metal substrate and the fluoropolymer layer can have good bonding strength by a heating process, and its peel strength can be, for example, greater than or equal to 1 kgf/cm. Since no additional adhesive layer and no surface treatment are required during the formation of the composite substrate 100, it is beneficial to thin the composite substrate 100 and simplify the process. Since no adhesive layer is required, the problem of adhesive hardening during secondary coating will not occur. Based on the above, the manufacturing method disclosed in the present disclosure can obtain the composite substrate 100 through a simple process, which is beneficial to reduce the manufacturing cost.

In some embodiments, the first fluoropolymer layer 110 and the second fluoropolymer layer 130 are solid films and independently include: 30 parts by weight to 50 parts by weight of a fluoropolymer, 1 part by weight to 5 parts by weight of a dispersant, 1 part by weight to 10 parts by weight of a plurality of inorganic particles, and 1 part by weight to 5 parts by weight of a macromolecule resin. The above materials are mixed with each other. The macromolecule resin is different from the fluoropolymer. In more detail, the macromolecule resin and the fluoropolymer are different materials, and the monomer unit structures of the two are different. For example, the macromolecule resin does not contain fluorine. The content of the fluoropolymer, the dispersant, the inorganic particles, and the macromolecule resin can be any positive integer within the above numerical ranges. For example, the fluoropolymer is 30, 35, 40, 45, or 50 parts by weight, the dispersant is 1, 2, 3, 4, or 5 parts by weight, the inorganic particles are 1, 2, 3, 4, 5, 6, 7, 8, 9, or 10 parts by weight, and the macromolecule resin is 1, 2, 3, 4, or 5 parts by weight. When the content of the fluoropolymer, the dispersant, the inorganic particles, and the macromolecule resin are within the above numerical ranges, the first fluoropolymer layer 110, the liquid crystal polymer layer 120, and the second fluoropolymer layer 130 can have good bonding strength, and the composite substrate 100 can have a low dielectric constant, a low loss factor, and a low coefficient of thermal expansion (CTE). In some embodiments, the dielectric constant (Dk) of the composite substrate 100 at 10 GHz is 2.0 to 3.0, such as 2.0, 2.4, 2.6, 2.8, or 3.0. In some embodiments, the loss factor (Df) of the composite substrate 100 at 10 GHz is 0.0004 to 0.02, such as 0.0004, 0.0006, 0.0008, 0.001, 0.005, 0.01, 0.015, or 0.02. In some embodiments, the CTE of the composite substrate 100 is 5 ppm/° C. to 40 ppm/° C., such as 5, 10, 15, 20, 25, 30, 35, or 40 ppm/° C. Since the CTE of the composite substrate 100 is similar to the CTE of the metal, when a metal substrate is attached to the surface of the composite substrate 100, the composite substrate 100 is not prone to warping. In some embodiments, the water absorption rate of the composite substrate 100 is less than or equal to 0.04%. Since the composite substrate 100 can have a low water absorption rate, it has good stability and is suitable for use in high-frequency circuit substrates or high-speed transmission line circuits.

The first fluoropolymer layer 110 and the second fluoropolymer layer 130 can be formed by curing fluoropolymer dispersion liquid or by cutting a fluoropolymer solid film. In some embodiments, the fluoropolymer dispersion liquid used to form the first fluoropolymer layer 110 and the second fluoropolymer layer 130 independently includes: 30 parts by weight to 50 parts by weight of a fluoropolymer, 1 part by weight to 5 parts by weight of a dispersant, 1 part by weight to 10 parts by weight of a plurality of inorganic particles, 1 part by weight to 5 parts by weight of a macromolecule resin, and 30 parts by weight to 60 parts by weight of a solvent. The parts by weight of the fluoropolymer, the dispersant, the inorganic particles, the macromolecule resin, and the solvent can be any positive integer within the above numerical ranges. For example, the solvent is 30, 35, 40, 45, 50, 55, or 60 parts by weight. In some embodiments, the solvent includes N-methyl-2-pyrrolidone (NMP), methyl ethyl ketone (MEK), N,N-dimethylacetamide (DMAC), or combinations thereof. The above solvents can allow the fluoropolymer, dispersant, inorganic particles, and macromolecule resin to be homogeneously mixed.

In some embodiments, the fluoropolymer includes polytetrafluoroethylene (PTFE), ethylene-tetrafluoroethylene copolymer (ETFE copolymer), tetrafluoroethylene-hexafluoropropene copolymer, tetrafluoroethylene-perfluoroalkyl vinyl ether copolymer, polychlorotrifluoroethylene (PCTFE), ethylene-trifluorochloroethylene copolymer (ECTFE copolymer), trifluorochloroethylene-tetrafluoroethylene copolymer, polyvinylidene difluoride (PVDF), tetrafluoroethylene-hexafluoropropene-difluoroethylene copolymer, tetrafluoroethylene-perfluoroalkoxy vinyl ether copolymer, or combinations thereof. The tetrafluoroethylene-perfluoroalkyl vinyl ether copolymer includes, for example, tetrafluoroethylene-perfluoroethyl vinyl ether copolymer, tetrafluoroethylene-perfluoro-n-propyl vinyl ether copolymer, or combinations thereof. In some embodiments, in the tetrafluoroethylene-perfluoroalkyl vinyl ether copolymer, the alkyl group of the perfluoroalkyl vinyl ether is linear or branched, and is, for example, methyl, ethyl, n-propyl, isopropyl, n-butyl, isobutyl, sec-butyl, t-butyl, or pentyl. In some embodiments, the tetrafluoroethylene-perfluoroalkyl vinyl ether copolymer is polymerized by a single type of perfluoroalkyl vinyl ether and tetrafluoroethylene, in which the perfluoroalkyl vinyl ether may be 1 wt % to 15 wt %, such as 1, 2, 4, 6, 8, 10, 12, 14, or 15 wt %. In some embodiments, the tetrafluoroethylene-perfluoroalkyl vinyl ether copolymer is polymerized by different kinds of perfluoroalkyl vinyl ethers and tetrafluoroethylene, and the perfluoroalkyl vinyl ethers include, for example, perfluoromethyl vinyl ether and perfluoropropyl vinyl ether. In the reactants for synthesizing the copolymer, the perfluoromethyl vinyl ether may be 0.5 wt % to 13 wt %, and the perfluoropropyl vinyl ethe may be 0.5 wt % to 3 wt %. The above-mentioned fluoropolymers has at least the effect of being closely bonded to the liquid crystal polymer layer and/or the metal substrate at high temperature. In addition, when the composite substrate 100 is used as a circuit board, it may be necessary to form a plurality of holes in the composite substrate 100 by ultraviolet laser drilling, and to fill the holes with conductive materials. Compared to polymers without fluorine, fluorine polymers absorb ultraviolet light more easily, and thus it is easier to form conductive materials in the composite substrate 100 by ultraviolet laser drilling.

In some embodiments, the inorganic particles include titanium dioxide, silicon dioxide, aluminum oxide, zirconium dioxide, magnesium oxide, calcium oxide, talc, aluminium hydroxide, magnesium hydroxide, barium sulfate, calcium carbonate, potassium titanate, clay, or combinations thereof. In some embodiments, the average particle size of the inorganic particles is 0.1 μm to 20 μm, such as, 0.1, 0.5, 1, 2, 4, 6, 8, 10, 12, 14, 16, 18, or 20 μm. The inorganic particles can reduce the coefficients of thermal expansion (CTE) of the first fluoropolymer layer 110 and the second fluoropolymer layer 130, thereby preventing the composite substrate 100 from warping. In some embodiments, the CTEs of the first fluoropolymer layer 110 and the second fluoropolymer layer 130 are 5 ppm/° C. to 40 ppm/° C., for example, 5, 10, 15, 20, 25, 30, 35, or 40 ppm/° C.

In some embodiments, the dispersant includes ethyl acetate, butyl acetate, ethylene glycol ethyl ether acetate, phthalate, propylene glycol methyl ether acetate, urethane acrylate, tripropylene glycol diacrylate, 1,6-hexanediol diacrylate, propylene glycol monomethyl ether acetate, ethylene glycol methyl ether acetate, 2-methoxyethyl acetate, ethyl acrylate, fatty acid polyethylene glycol ester, vinyl formate, methyl acrylic ester, or combinations thereof. The methyl acrylic ester may be methyl methacrylate. The above dispersants can enhance the dispersibility of the inorganic particles, so that the inorganic particles are uniformly dispersed in the first fluoropolymer layer 110 and/or the second fluoropolymer layer 130, so as to uniformly reduce the CTEs of the first fluoropolymer layer 110 and the second fluoropolymer layer 130.

In some embodiments, the macromolecule resin includes poly (acrylic acid), polyimide, a liquid crystal polymer, a cyclic olefin polymer, a cyclic olefin copolymer, a styrene-butadiene copolymer, a styrene-ethylene copolymer, a styrene-propylene copolymer, a styrene-butylene copolymer, a polyester, a polyolefin, polyphenylene ether, polyphenylene sulfide, styrene, polycarbonate, polyarylate, maleimide resin, polysulfone, polyarylsulfone, polyaryletherketone, epoxy resin, polyvinyl acetate, polyaryl amide, polyetheretherketone, poly (ether sulfone), polyphenylene oxide, polyoxymethylene, polyetherimide, polysiloxane, or combinations thereof. In some embodiments, the weight average molecular weight of the macromolecule resin is 10,000 to 500,000, for example, 10,000, 20,000, 40,000, 60,000, 80,000, 100,000, 200,000, 300,000, 400,000, or 500,000. When the first fluoropolymer layer 110 and/or the second fluoropolymer layer 130 contain PAA and/or polyimide, and the composite substrate 100 is used as a circuit board, the PAA and/or the polyimide easily absorb UV laser, thereby making it easy to form holes in the composite substrate 100 by laser drilling, thereby facilitating the formation of conductive circuits in the composite substrate 100.

The liquid crystal polymer layer 120 can be formed by curing a liquid crystal polymer adhesive layer, or by forming a liquid crystal polymer into a thin film by injection molding or extrusion molding. In some embodiments, the liquid crystal polymer adhesive layer includes a soluble liquid crystal polymer, an aromatic polymer, and a solvent. The solvent of the liquid crystal polymer adhesive layer can be substantially removed after curing. The liquid crystal polymer adhesive layer can be coated at 40° C. to 160° C., for example, 40, 60, 80, 100, 120, 140, or 160° C. Compared to a thin film formed of an insoluble liquid crystal polymer, the liquid crystal polymer layer 120 formed of the liquid crystal polymer adhesive layer can reduce process time and equipment cost, and the liquid crystal polymer layer 120 is less likely to peel or break due to external stress. In addition, the liquid crystal polymer adhesive layer has high plasticity, so it is easy to form a flat surface during the process of manufacturing the liquid crystal polymer layer 120, thereby reducing the situation where the circuit formed subsequently is damaged by adhesion, extrusion, etc. due to the uneven surface. In some embodiments, the soluble liquid crystal polymer includes a plurality of monomer units, wherein the monomer units have a structure as shown in formula (1):

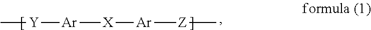

Ar is 1,4-phenylene, 1,3-phenylene, 2,6-naphthalene, or 4,4′-biphenylene, Y is O or NH, Z is C═O, X is NH, amide, imino, amidino, aminocarbonylamino, aminothiocarbonyl, aminocarbonyloxy, aminosulfonyl, aminosulfonyloxy, aminosulfonylamino, carboxyl ester, (carboxyl ester)amino, (alkoxycarbonyl)oxy, alkoxycarbonyl, hydroxyamino, alkoxyamino, cyanato, isocyanato, or combinations thereof. In some embodiments, the aromatic macromolecule includes aromatic polyester, aromatic polyamide, poly(p-phenylene terephthalamide), poly(p-phenylene benzobisoxazole), a copolymer of p-hydroxybenzoic acid and 6-hydroxy-2-naphthoic acid, or combinations thereof. In some embodiments, the solvent includes N-methyl-2-pyrrolidone, N,N-dimethylacetamide, γ-butyrolactone, N,N-dimethyl formamide, 2-butoxyethanol, 2-ethoxyethanol, or a combination thereof.

In some embodiments, the liquid crystal polymer adhesive layer includes a liquid crystal polymer powder and a solvent. In some embodiments, the liquid crystal polymer powder includes a thermotropic liquid crystal polymer resin. In some embodiments, the curing temperature of the liquid crystal polymer adhesive layer is at least higher than the liquid crystal transition temperature of the thermotropic liquid crystal polymer resin. The thermotropic liquid crystal polymer resin may be a high heat-resistant liquid crystal polymer resin with a liquid crystal transition temperature greater than 330° C., a medium heat-resistant liquid crystal polymer resin with a liquid crystal transition temperature of 280° C. to 320° C., or a low heat-resistant liquid crystal polymer resin with a liquid crystal transition temperature less than 240° C. For example, the high heat-resistant liquid crystal polymer resin can be polymerized from p-hydroxybenzoic acid, terephthalic acid, and 4,4′-dioxydiphenol. For example, the medium heat-resistant liquid crystal polymer resin can be polymerized from p-hydroxybenzoic acid and 6-hydroxy-2-naphthoic acid. For example, the low heat-resistant liquid crystal polymer resin can be polymerized from polyethylene terephthalate and p-hydroxybenzoic acid. In some embodiments, the average particle size of the liquid crystal polymer powder is 1 nm to 1000 μm, such as 1 nm, 5 nm, 10 nm, 15 nm, 20 nm, 30 nm, 50 nm, 70 nm, 90 nm, 100 nm, 1 μm, 5 μm, 10 μm, 15 μm, 20 μm, 50 μm, 100 μm, 200 μm, 300 μm, 400 μm, 500 μm, 600 μm, 700 μm, 800 μm, 900 μm, or 1000 μm. The liquid crystal polymer powder having the above average particle size can have good dispersibility in the solvent. In some embodiments, the solvent includes amide, acid, alcohol, ketone, aromatic solvent, water, or combinations thereof. In some embodiments, the amide includes N,N-dimethylacetamide, hexamethylphosphoramide, N-methylpyrrolidone, N,N,N′, N′-tetramethylurea, N-methyl caprolactam, N-acetylpyrrolidone, N,N-dimethylpropionamide, N-methyl-piperidone, 1,3-dimethyl-2-imidazolidinone, N,N,N′, N′-tetramethylmalonamide, dimethylformamide, or combinations thereof. In some embodiments, the acid includes sulfuric acid, hydrofluoric acid, trifluoromethanesulfonic acid, trifluoroacetic acid, a mixed solution of trifluoroacetic acid/dichloromethane, a mixed solution of trifluoroacetic acid/dichloromethane/tetrachloroethylene, sulfurochloridic acid, or combinations thereof. In some embodiments, the alcohol includes hexafluoroisopropanol. In some embodiments, the aromatic solvent includes toluene, xylene, p-chlorophenol, a mixed solution of p-chlorophenol/tetrachloroethane, a mixed solution of o-dichlorobenzene/p-chlorophenol, a mixed solution of phenol/tetrachloroethane/p-chlorophenol, a mixed solution of phenol/tetrachloroethane, a mixed solution of phenol/trichloromethane, toluenol, o-chlorophenol, pentafluorophenol, p-fluorophenol, or combinations thereof. In some embodiments, the weight ratio of the liquid crystal polymer powder to the solvent (liquid crystal polymer powder/solvent) is 1:100 to 90:100, such as 1:100, 10:100, 20:100, 30:100, 40:100, 50:100, 60:100, 70:100, 80:100, 90:100. When the weight ratio falls within the above range, the liquid crystal polymer powder can be uniformly dispersed in the solvent.

In some embodiments, the liquid crystal polymer layer 120 is formed by forming a liquid crystal polymer into a thin film by injection molding or extrusion molding. In some embodiments, the liquid crystal polymer is polymerized by a reactant composition. The reactant composition includes a plurality of first monomers, a plurality of second monomers, a plurality of third monomers, a plurality of fourth monomers, or combinations thereof. The first monomers are aromatic dicarboxylic acids, aliphatic dicarboxylic acids, or a combination thereof, the second monomers are aromatic hydroxycarboxylic acids, the third monomers are aromatic diols, aliphatic diols, or a combination thereof, and the fourth monomers are aromatic diamines, aromatic hydroxyamines, aromatic aminocarboxylic acids, or combinations thereof. For example, the first monomers include

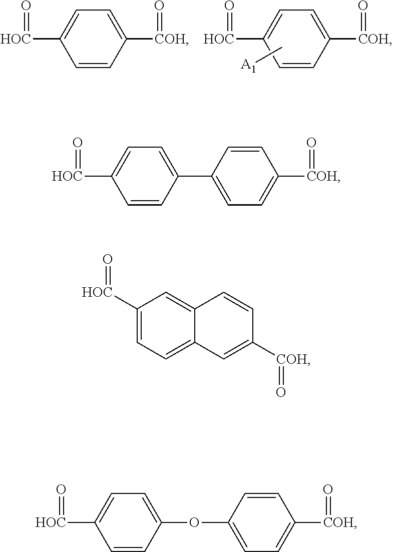

HOOC(CH₂)ₙCOOH (n is an integer from 2 to 12), or combinations thereof, but are not limited thereto. A₁ is a halogen group or an alkyl group. The halogen group is, for example, a fluoro group, a chloro group, a bromo group, or an iodo group. The alkyl group is, for example, a methyl group, an ethyl group, a n-propyl group, or an isopropyl group. For example, the second monomers include

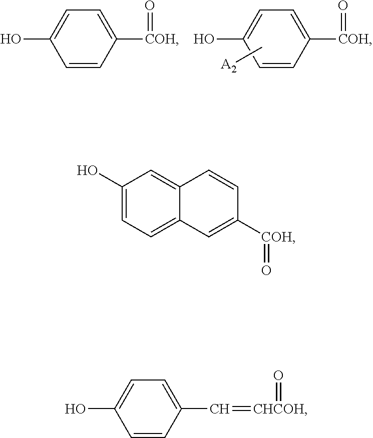

or combinations thereof, but are not limited thereto. A₂ is a halogen group or an alkyl group. The halogen group is, for example, a fluoro group, a chloro group, a bromo group, or an iodo group. The alkyl group is, for example, a methyl group, an ethyl group, a n-propyl group, or an isopropyl group. For example, the third monomers include

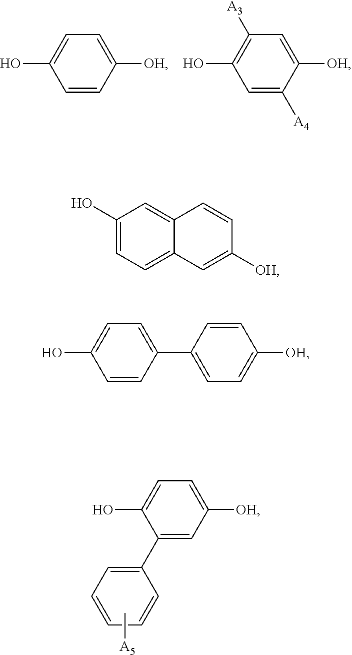

HO(CH₂)OH (n is an integer from 2 to 12), or combinations thereof, but are not limited thereto. A₃ and A₄ are independently a halogen group or an alkyl group, A₅ is H, a halogen group, or an alkyl group, the halogen group is, for example, a fluoro group, a chloro group, a bromo group, or an iodo group, and the alkyl group is, for example, a methyl group, an ethyl group, a n-propyl group, or an isopropyl group. For example, the fourth monomers include

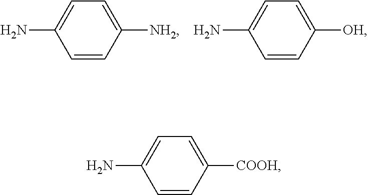 [SMILES: Nc1ccc(N)cc1 ; Nc1ccc(O)cc1 ; Nc1ccc(C(=O)O)cc1]

or combinations thereof, but are not limited thereto. In some embodiments, the liquid crystal polymer includes the following monomer units:

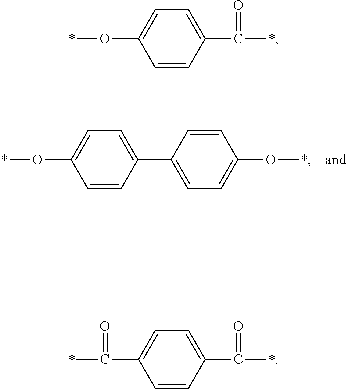

In some embodiments, the liquid crystal polymer includes the following monomer units:

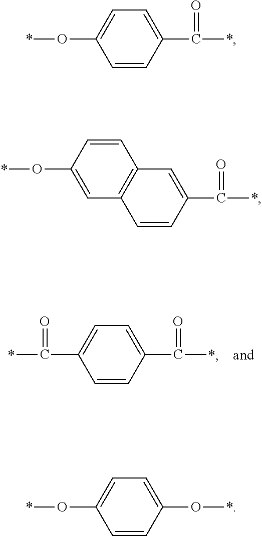

In some embodiments, the liquid crystal polymer includes the following monomer units:

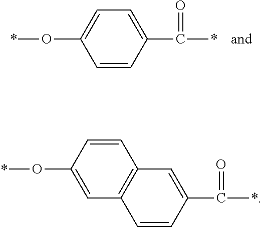

In some embodiments, the liquid crystal polymer includes the following monomer units:

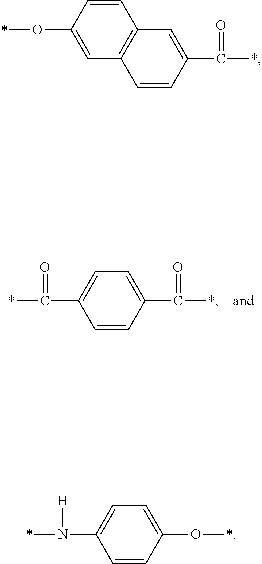

In some embodiments, the liquid crystal polymer includes the following monomer units:

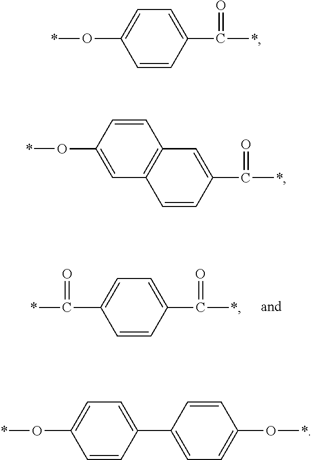

In some embodiments, the liquid crystal polymer includes the following monomer units:

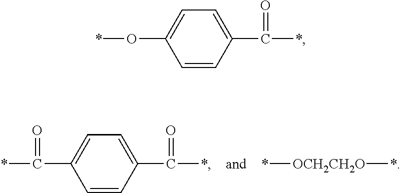

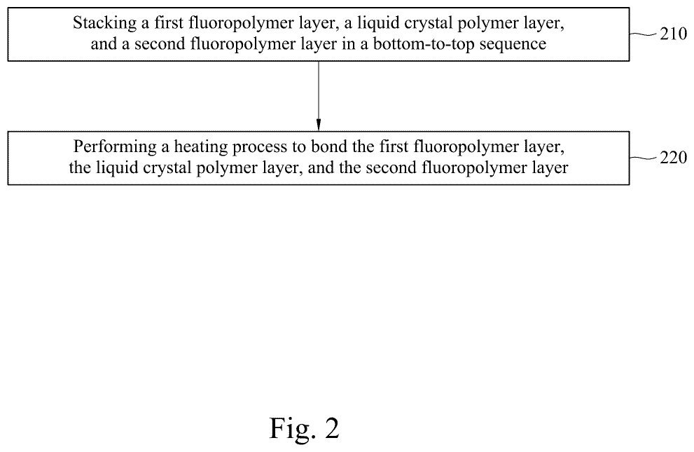

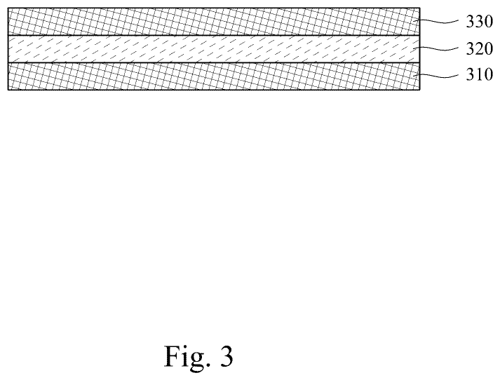

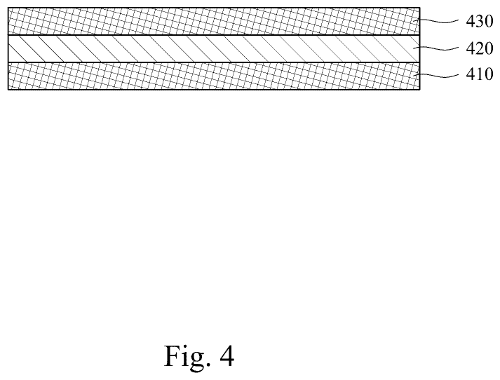

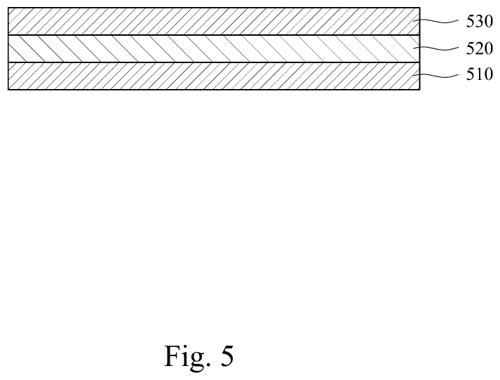

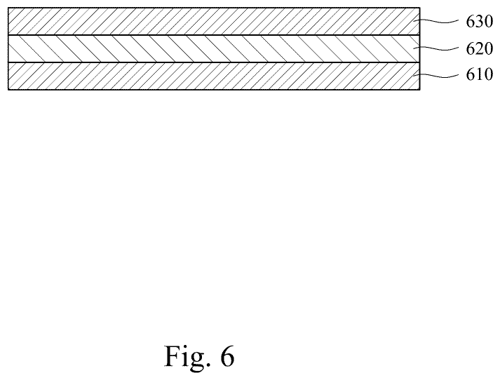

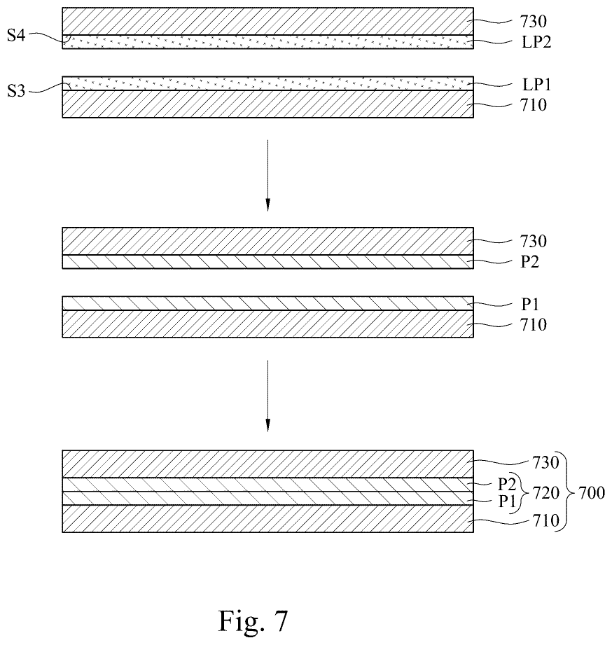

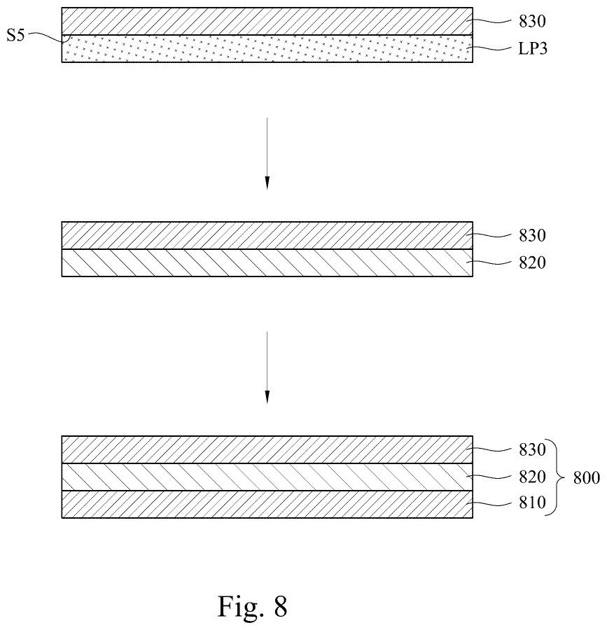

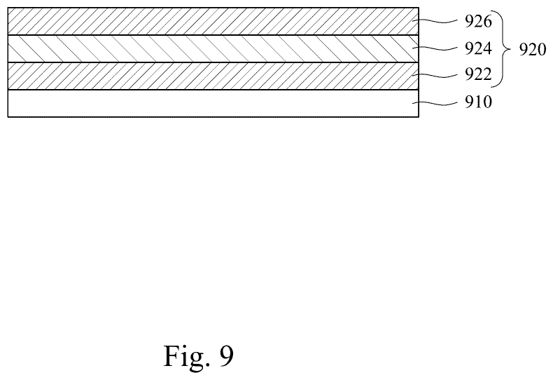

The present disclosure provides a method for manufacturing a composite substrate. FIG. 2 is a flow chart of a method 200 for manufacturing a composite substrate according to various embodiments of the present disclosure. The method includes operation 210 and operation 220. FIG. 3, FIG. 4, FIG. 5, FIG. 6, FIG. 7, FIG. 8, FIG. 9, FIG. 10, FIG. 11, and FIG. 12 are respectively schematic cross-sectional views of intermediate stages of manufacturing a composite substrate according to various embodiments of the present disclosure. Although below using a series of operations or steps described in this method disclosed, the order of these operations or steps shown should not be construed to limit the present disclosure. For example, certain operations or steps may be performed in different orders and/or concurrently with other steps. Moreover, not all steps must be performed in order to achieve the depicted embodiment of the present disclosure. Furthermore, each operation or procedure described herein may contain several sub-steps or actions.

Please refer to FIG. 2 and FIG. 3 simultaneously. In operation 210, a first fluoropolymer layer 310, a liquid crystal polymer layer 320, and a second fluoropolymer layer 330 are stacked in a bottom-to-top sequence. The first fluoropolymer layer 310 and the second fluoropolymer layer 330 are respectively dispersion liquid layers, and the liquid crystal polymer layer 320 is an adhesive layer. In more detail, a first fluoropolymer dispersion liquid, a liquid crystal polymer adhesive, and a second fluoropolymer dispersion liquid can be extruded simultaneously by an extruder with three openings to simultaneously coat and form the first fluoropolymer layer 310, the liquid crystal polymer layer 320 and the second fluoropolymer layer 330. The first fluoropolymer layer 310 and the second fluoropolymer layer 330 independently include: 30 parts by weight to 50 parts by weight of a fluoropolymer, 1 part by weight to 5 parts by weight of a dispersant, 1 part by weight to 10 parts by weight of a plurality of inorganic particles, 1 part by weight to 5 parts by weight of a macromolecule resin, and 30 parts by weight to 60 parts by weight of a solvent. In some embodiments, the solvent includes N-methyl-2-pyrrolidone (NMP), methyl ethyl ketone (MEK), N,N-dimethylacetamide (DMAC), or combinations thereof. The materials and effects of the fluoropolymers, the dispersants, the inorganic particles and the macromolecule resins of the first fluoropolymer layer 310 and the second fluoropolymer layer 330 are the same as those of the fluoropolymers, the dispersants, the inorganic particles, and the macromolecule resins of the first fluoropolymer layer 110 and the second fluoropolymer layer 130, so they will not be described in detail. In some embodiments, the liquid crystal polymer layer 320 includes a soluble liquid crystal polymer, an aromatic polymer, and a solvent. In other embodiments, the liquid crystal polymer layer 320 includes a liquid crystal polymer powder and a solvent. In operation 220, a heating process is performed to bond the first fluoropolymer layer 310, the liquid crystal polymer layer 320, and the second fluoropolymer layer 330, thereby forming the composite substrate 100 as shown in FIG. 1. In some embodiments, the temperature of the heating process is 200° C. to 400° C., such as 200, 220, 240, 260, 280, 300, 320, 340, 360, 380, or 400° C. In some embodiments, the temperature of the heating process is the glass transition temperature (T_{g}) of the fluoropolymer to the melting point (Tₘ) of the fluoropolymer +40° C., such as Tₘ, Tₘ+10, Tₘ+20, Tₘ+30, or Tₘ+40° C. In some embodiments, the heating time of the heating process is 1 minute to 300 minutes, for example, 1, 5, 10, 20, 30, 40, 50, 100, 150, 200, 250, or 300 minutes. Within the above temperature range and the heating time range, the first fluoropolymer layer 310, the liquid crystal polymer layer 320, and the second fluoropolymer layer 330 can have good bonding strength, and the peel strength of these film layers can be, for example, greater than or equal to 1 kgf/cm. Therefore, the composite substrate 100 prepared by the embodiment shown in FIG. 3 can be used as a high-frequency and high-speed substrate. In more detail, after performing the heating process, the solvent in the first fluoropolymer layer 310, the liquid crystal polymer layer 320, and the second fluoropolymer layer 330 can be substantially removed, so that these film layers are dried to form the solid film as shown in FIG. 1.

Please refer to FIG. 2 and FIG. 4 at the same time. In operation 210, a first fluoropolymer layer 410, a liquid crystal polymer layer 420, and a second fluoropolymer layer 430 are stacked in a bottom-to-top sequence. The first fluoropolymer layer 410 and the second fluoropolymer layer 430 are respectively dispersion liquid layers, and the liquid crystal polymer layer 420 is a solid film. In more detail, first fluoropolymer dispersion liquid and second fluoropolymer dispersion liquid can be applied to the upper and lower surfaces of the liquid crystal polymer layer 420, respectively, to form the first fluoropolymer layer 410 and the second fluoropolymer layer 430. The formation methods, materials, thickness, and effects of the liquid crystal polymer layer 420 are the same as the formation method, materials, thickness, and effects of the liquid crystal polymer layer 120 in FIG. 1, and the formation methods, materials, thicknesses, and effects of the first fluoropolymer layer 410 and the second fluoropolymer layer 430 are the same as the formation methods, materials, and effects of the first fluoropolymer layer 310 and the second fluoropolymer layer 330 in FIG. 3, so they will not be described in detail. In operation 220, a heating process is performed to bond the first fluoropolymer layer 410, the liquid crystal polymer layer 420, and the second fluoropolymer layer 430, thereby forming the composite substrate 100 shown in FIG. 1. The temperature, time, and effect of this heating process are the same as the temperature, time, and effect of the heating process in the embodiment of FIG. 3, so they will not be described in detail.

Please refer to FIG. 2 and FIG. 5 at the same time. In operation 210, a first fluoropolymer layer 510, a liquid crystal polymer layer 520, and a second fluoropolymer layer 530 are stacked in a bottom-to-top sequence. The liquid crystal polymer layer 520, the first fluoropolymer layer 510, and the second fluoropolymer layer 530 are solid films, respectively, and thus substantially do not contain a solvent. The formation methods, materials, thicknesses, and effects of the liquid crystal polymer layer 520, the first fluoropolymer layer 510, and the second fluoropolymer layer 530 are the same as the formation methods, materials, thicknesses, and effects of the liquid crystal polymer layer 120, the first fluoropolymer layer 110, and the second fluoropolymer layer 130 in FIG. 1, and thus they will not be described in detail. In operation 220, a heating process is performed to bond the first fluoropolymer layer 510, the liquid crystal polymer layer 520, and the second fluoropolymer layer 530, thereby forming the composite substrate 100 as shown in FIG. 1. The temperature, time, and effect of the heating process are the same as those of the heating process of the embodiment of FIG. 3, so they will not be described in detail. In addition, in the embodiment shown in FIG. 5, while performing the heating process, a pressing process is performed to heat-press the first fluoropolymer layer 510, the liquid crystal polymer layer 520, and the second fluoropolymer layer 530, in which the pressure of the pressing process is 1 kg/cm² to 100 kg/cm², for example, 1, 5, 10, 20, 30, 40, 50, 60, 70, 80, 90 or 100 kg/cm². When the pressure falls within the above range, the first fluoropolymer layer 510, the liquid crystal polymer layer 520, and the second fluoropolymer layer 530 can have good bonding strength, and the peel strength of these film layers can be, for example, greater than or equal to 1 kgf/cm. When the heating process and the pressing process are performed simultaneously, the temperature required for bonding can be reduced.

Please refer to FIG. 2 and FIG. 6 at the same time. In operation 210, a first fluoropolymer layer 610, a liquid crystal polymer layer 620, and a second fluoropolymer layer 630 are stacked in a bottom-to-top sequence. The liquid crystal polymer layer 620, the first fluoropolymer layer 610, and the second fluoropolymer layer 630 are respectively solid films, and therefore substantially do not contain a solvent. The formation methods, materials, thicknesses, and effects of the liquid crystal polymer layer 620, the first fluoropolymer layer 610, and the second fluoropolymer layer 630 are the same as the formation methods, materials, thicknesses, and effects of the liquid crystal polymer layer 120, the first fluoropolymer layer 110, and the second fluoropolymer layer 130 in FIG. 1, and thus they will not be described in detail. In operation 220, a heating process is performed to bond the first fluoropolymer layer 610, the liquid crystal polymer layer 620, and the second fluoropolymer layer 630, thereby forming the composite substrate 100 as shown in FIG. 1. The temperature, time, and effect of this heating process are the same as those of the heating process of the embodiment of FIG. 3, so they will not be described in detail. In the embodiment shown in FIG. 6, when performing the heating process, no additional pressure is applied to the first fluoropolymer layer 610, the liquid crystal polymer layer 620, and the second fluoropolymer layer 630, but the first fluoropolymer layer 610, the liquid crystal polymer layer 620, and the second fluoropolymer layer 630 are bonded by high temperature. In some embodiments, the method further includes: when performing the heating process, placing the first fluoropolymer layer 610, the liquid crystal polymer layer 620, and the second fluoropolymer layer 630 in a nitrogen gas oven or an infrared oven, thereby improving the efficiency and yield of bonding.

Please refer to FIG. 2 and FIG. 7 at the same time. In operation 210, a first fluoropolymer layer 710, a liquid crystal polymer layer 720, a the second fluoropolymer layer 730 are stacked in a bottom-to-top sequence. In operation 220, a heating process is performed to bond the first fluoropolymer layer 710, the liquid crystal polymer layer 720, and the second fluoropolymer layer 730 to form a composite substrate 700. The temperature, time, and effect of this heating process are the same as those of the heating process of the embodiment of FIG. 3, so they will not be described in detail. In some embodiments, a pressing process can be performed with reference to the embodiment of FIG. 5 to heat-press the first fluoropolymer layer 710, the liquid crystal polymer layer 720, and the second fluoropolymer layer 730. Before stacking the first fluoropolymer layer 710, the liquid crystal polymer layer 720, and the second fluoropolymer layer 730 in order from bottom to top, a first liquid crystal polymer adhesive layer LP1 is coated to cover the upper surface S3 of the first fluoropolymer layer 710, and a second liquid crystal polymer adhesive layer LP2 is coated to cover the lower surface S4 of the second fluoropolymer layer 730. The first liquid crystal polymer adhesive layer LP1 and the second liquid crystal polymer adhesive layer LP2 are cured to form the first portion P1 and the second portion P2 of the liquid crystal polymer layer 720, respectively. The first portion P1 and the second portion P2 of the liquid crystal polymer layer 720 are brought into contact with each other, and a heating process is performed to bond the first fluoropolymer layer 710, the liquid crystal polymer layer 720, and the second fluoropolymer layer 730, in which the first portion P1 and the second portion P2 are bonded to each other. The materials of the first liquid crystal polymer adhesive layer LP1 and the second liquid crystal polymer adhesive layer LP2 are the same as the materials of the liquid crystal polymer adhesive layer used to manufacture the liquid crystal polymer layer 120, and thus they will not be described in detail.

Please refer to FIG. 2 and FIG. 8 at the same time. In operation 210, a first fluoropolymer layer 810, a liquid crystal polymer layer 820, and a second fluoropolymer layer 830 are stacked in a bottom-to-top sequence. In operation 220, a heating process is performed to bond the first fluoropolymer layer 810, the liquid crystal polymer layer 820, and the second fluoropolymer layer 830 to form a composite substrate 800. The temperature, time, and effect of this heating process are the same as the temperature, time, and effect of the heating process in the embodiment of FIG. 3, so they will not be described in detail. In some embodiments, a pressing process can be performed with reference to the embodiment of FIG. 5 to heat-press the first fluoropolymer layer 810, the liquid crystal polymer layer 820, and the second fluoropolymer layer 830. Before stacking the first fluoropolymer layer 810, the liquid crystal polymer layer 820, and the second fluoropolymer layer 830 in order from bottom to top, a liquid crystal polymer adhesive layer LP3 is coated to cover the lower surface S5 of the second fluoropolymer layer 830. The liquid crystal polymer adhesive layer LP3 is cured to form the liquid crystal polymer layer 820. The liquid crystal polymer layer 820 is brought into contact with the first fluoropolymer layer 810, and a heating process is performed to bond the first fluoropolymer layer 810, the liquid crystal polymer layer 820, and the second fluoropolymer layer 830. The material of the liquid crystal polymer adhesive layer LP3 is the same as the material of the liquid crystal polymer adhesive layer used to manufacture the liquid crystal polymer layer 120, so it will not be described in detail.

Referring to FIG. 9, a composite substrate 900 includes a metal substrate 910 and a composite substrate 920 that are bonded to each other. The composite substrate 920 includes a first fluoropolymer layer 922, a liquid crystal polymer layer 924, and a second fluoropolymer layer 926 that are stacked in a bottom-to-top sequence. The composite substrate 920 can be manufactured with reference to any of the embodiments described in FIG. 3 to FIG. 8 above. In some embodiments, a method for manufacturing the composite substrate 900 includes: performing a heating process to bond the metal substrate 910 and the composite substrate 920. In some embodiments, the temperature of the heating process is 200° C. to 400° C., for example, 200, 220, 240, 260, 280, 300, 320, 340, 360, 380, or 400° C. In some embodiments, the temperature of the heating process is from the glass transition temperature (T_{g}) of the fluoropolymer to the melting point (Tₘ) of the fluoropolymer +40° C., such as Tₘ, Tₘ+10, Tₘ+20, Tₘ+30, or Tₘ+40° C. In some embodiments, the heating time of the heating process is 1 minute to 300 minutes, such as 1, 5, 10, 20, 30, 40, 50, 100, 150, 200, 250, or 300 minutes. Within the above temperature range, the composite substrate 920 and the metal substrate 910 can have good bonding strength, and the peel strength of these film layers can be, for example, greater than or equal to 1 kgf/cm. In some embodiments, a pressing process is performed during the heating process to heat-press the metal substrate 910 and the composite substrate 920, in which the pressure of the pressing process is 1 kg/cm² to 100 kg/cm², for example, 1, 5, 10, 20, 30, 40, 50, 60, 70, 80, 90, or 100 kg/cm². When the pressure falls within the above range, the metal substrate 910 and the composite substrate 920 can have good bonding strength, and the peel strength of these film layers can be, for example, greater than or equal to 1 kgf/cm. In some embodiments, the manufacturing method of the composite substrate 900 includes: stacking a first fluoropolymer layer 922, a liquid crystal polymer layer 924, and a second fluoropolymer layer 926 in a bottom-to-top sequence on the metal substrate 910, and performing a heating process to bond the metal substrate 910, the first fluoropolymer layer 922, the liquid crystal polymer layer 924, and the second fluoropolymer layer 926. In some embodiments, the first fluoropolymer layer 922, the liquid crystal polymer layer 924, and the second fluoropolymer layer 926 are solid films, respectively. In some embodiments, the thickness of the metal substrate 910 is 1 μm to 72 μm, such as 1, 5, 10, 20, 30, 40, 50, 60, 70, or 72 μm. In some embodiments, the metal substrate 910 includes copper, aluminum, iron, silver, palladium, nickel, chromium, molybdenum, tungsten, zinc, chromium, manganese, cobalt, gold, tin, lead, stainless steel, or alloys thereof. In some embodiments, the metal substrate 910 is a copper foil, such as an electrolytic copper foil or a rolled copper foil.

Please refer to FIG. 10. A composite substrate 1000 includes a metal substrate 1010 and a composite substrate 1020 that are bonded to each other. The composite substrate 1020 includes a first fluoropolymer layer 1022′, a liquid crystal polymer layer 1024′, and a second fluoropolymer layer 1026′ that are stacked in order from bottom to top. In some embodiments, the material and structure of the metal substrate 1010 are the same as the material and structure of the metal substrate 910, and will not be described in detail. The manufacturing method for the composite substrate 1000 includes: stacking a first fluoropolymer layer 1022, a liquid crystal polymer layer 1024, and a second fluoropolymer layer 1026 in a bottom-to-top sequence on the metal substrate 1010. The first fluoropolymer layer 1022 and the second fluoropolymer layer 1026 are respectively dispersion liquid layers, and the liquid crystal polymer layer 1024 is an adhesive layer. Next, a heating process is performed to bond the metal substrate 1010, the first fluoropolymer layer 1022, the liquid crystal polymer layer 1024, and the second fluoropolymer layer 1026 to form the composite substrate 1000. The temperature, time, pressure, and effect of the heating process are the same as those of the embodiment of FIG. 9, so they will not be described in detail.

Referring to FIG. 11, a composite substrate 1100 includes a first metal substrate 1110, a second metal substrate 1120, and a composite substrate 1130 that are bonded to each other. The composite substrate 1130 includes a first fluoropolymer layer 1132, a liquid crystal polymer layer 1134, and a second fluoropolymer layer 1136 that are stacked in a bottom-to-top sequence. In some embodiments, the materials and structures of the first metal substrate 1110 and the second metal substrate 1120 are the same as the material and structure of the metal substrate 910, and will not be described in detail. The composite substrate 1130 can be manufactured with reference to any of the embodiments described in FIGS. 3 to 8 above. The method for manufacturing the composite substrate 1100 includes: stacking the first metal substrate 1110, the composite substrate 1130, and the second metal substrate 1120 in a bottom-to-top sequence. A heating process is performed to bond the first metal substrate 1110, the composite substrate 1130 and the second metal substrate 1120 to form the composite substrate 1100. The temperature, time, pressure and effect of the heating process are the same as those of the embodiment of FIG. 9, and they will not be described in detail.

Referring to FIG. 12, a composite substrate 1200 includes a composite substrate 1210 and a first metal substrate 1220 that are bonded to each other. The composite substrate 1210 can be manufactured with reference to any of the embodiments described in FIGS. 9 to 10. The composite substrate 1210 includes a second metal substrate 1212, a first fluoropolymer layer 1214, a liquid crystal polymer layer 1216, and a second fluoropolymer layer 1218 that are stacked in a bottom-to-top sequence. In some embodiments, the materials and structures of first metal substrate 1220 and second metal substrate 1212 are the same as the material and structure of metal substrate 910, and they will not be described in detail. The manufacturing method of the composite substrate 1100 includes: stacking the composite substrate 1210 and the first metal substrate 1220 in sequence from bottom to top. A heating process is performed to bond the first metal substrate 1220 and the composite substrate 1210. The temperature, time, pressure, and effect of this heating process are the same as those of the heating process in the embodiments of FIG. 9, so they will not be described in detail.

The following describes the features of the present disclosure more specifically with reference to Experimental Examples 1 to 2. Although the following examples are described, the materials, their amounts and ratios, processing details, processing procedures, etc., may be appropriately varied without exceeding the scope of the present disclosure. Accordingly, the present disclosure should not be interpreted restrictively by the examples described below.

### Experimental Example 1

### Manufacturing Composite Substrate and Measuring Properties of Composite Substrate

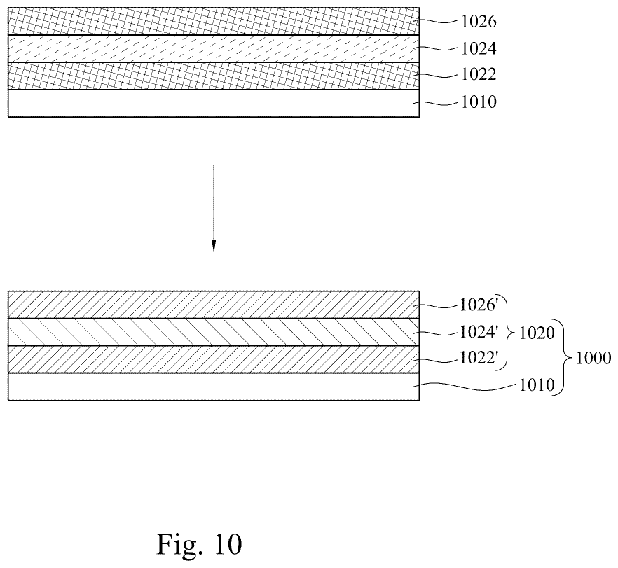

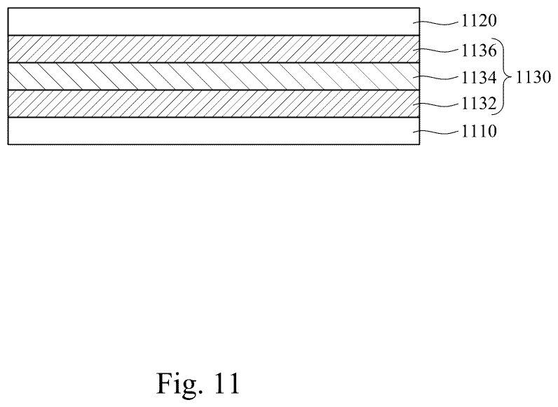

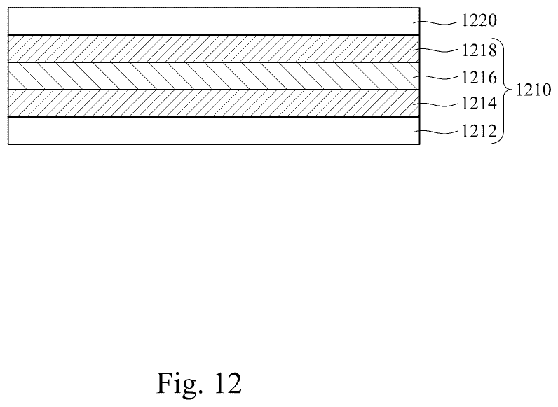

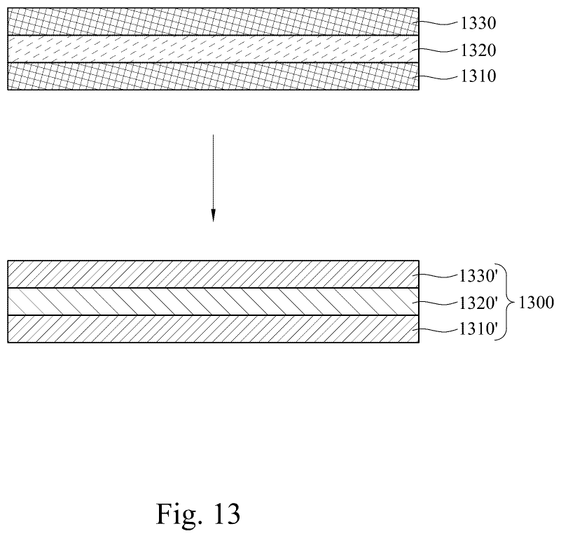

FIG. 13 is a schematic view of manufacturing a composite substrate 1300 of Experimental Example 1. A first fluoropolymer layer 1310, a liquid crystal polymer layer 1320, and a second fluoropolymer layer 1330 are stacked in a bottom-to-top sequence. The first fluoropolymer layer 1310 and the second fluoropolymer layer 1330 are respectively dispersion liquid layers and respectively includes tetrafluoroethylene-perfluoroalkyl vinyl ether copolymer, ethyl acetate, silicon dioxide particles, poly(acrylic acid), and N-methylpyrrolidone. The liquid crystal polymer layer 1320 is a solid film and has a melting point of 300° C. to 350° C. and a CTE of 18 ppm/° C. to 22 ppm/° C. In more detail, first fluoropolymer dispersion liquid and second fluoropolymer dispersion liquid can be applied to upper and lower surfaces of the liquid crystal polymer layer 1320, respectively, to form the first fluoropolymer layer 1310 and the second fluoropolymer layer 1330. A heating process is performed to bond the first fluoropolymer layer 1310, the liquid crystal polymer layer 1320, and the second fluoropolymer layer 1330 to remove the solvent in the first fluoropolymer layer 1310 and the second fluoropolymer layer 1330, thereby forming the composite substrate 1300. The composite substrate 1300 includes a first fluoropolymer layer 1310′, a liquid crystal polymer layer 1320′, and a second fluoropolymer layer 1330′ bonded in a bottom-to-top sequence. The manufacturing conditions and property test results of the composite substrate 1300 of Examples 1 to 8 are shown in the following Table 1. As can be seen from Table 1, the composite substrate 1300 of Examples 1 to 8 can have a peel strength of 1 kgf/cm to 1.3 kgf/cm, a dielectric constant (Dk) of 2.4 to 3.0, and a loss factor (Df) of 0.0026 to 0.0035, so they are suitable as high-frequency and high-speed substrates.

TABLE 1

| | Thickness of | Thickness of | Thickness of | | | | | | |
|---|---|---|---|---|---|---|---|---|---|
| | liquid crystal | first | second | Bonding | Heating | Peel | Dk | Df | |
| | polymer layer | fluoropolymer | fluoropolymer | temperature | time | strength | (10 | (10 | CTE |
| Example | (μm) | layer (μm) | layer (μm) | (° C.) | (minute) | (kgf/cm) | GHz) | GHz) | (ppm/° C.) |
| 1 | 25 | 12.5 | 12.5 | 300 | 60 | 1.0 | 2.9 | 0.0029 | 27 |
| 2 | 25 | 12.5 | 12.5 | 350 | 10 | 1.2 | 2.9 | 0.0029 | 27 |
| 3 | 25 | 25 | 25 | 300 | 60 | 1.1 | 2.7 | 0.0027 | 27 |
| 4 | 25 | 25 | 25 | 350 | 10 | 1.2 | 2.7 | 0.0027 | 27 |
| 5 | 50 | 12.5 | 12.5 | 300 | 60 | 1.1 | 2.6 | 0.0028 | 26 |
| 6 | 50 | 12.5 | 12.5 | 350 | 10 | 1.2 | 2.6 | 0.0028 | 26 |
| 7 | 50 | 25 | 25 | 300 | 60 | 1.1 | 2.4 | 0.0026 | 28 |
| 8 | 50 | 25 | 25 | 350 | 10 | 1.3 | 2.4 | 0.0026 | 28 |

### Experimental Example 2

### Manufacturing Composite Substrate and Measuring Properties of Composite Substrate

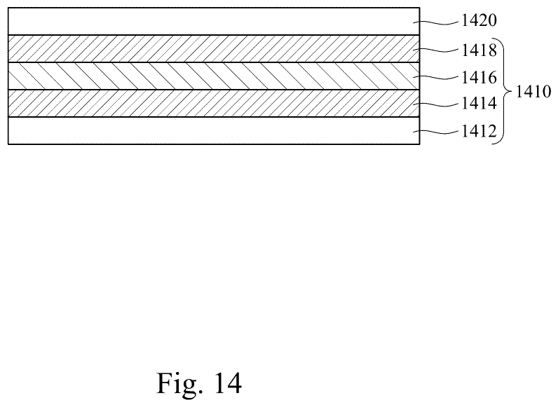

FIG. 14 is a schematic cross-sectional view of a composite substrate 1400 of Experimental Example 2. The manufacturing method of the composite substrate 1400 includes that a composite substrate 1410 and a copper foil substrate 1420 are stacked in a bottom-to-top sequence. A heating process is performed to bond the composite substrate 1410 and the copper foil substrate 1420. The composite substrate 1410 includes a copper foil substrate 1412, a first fluoropolymer layer 1414, a liquid crystal polymer layer 1416, and a second fluoropolymer layer 1418 stacked in a bottom-to-top sequence. The thicknesses of the copper foil substrate 1412 and the copper foil substrate 1420 are 12 μm, respectively. The first fluoropolymer layer 1414, the liquid crystal polymer layer 1416, and the second fluoropolymer layer 1418 are solid films. The first fluoropolymer layer 1414 and the second fluoropolymer layer 1418 respectively include tetrafluoroethylene-perfluoroalkyl vinyl ether copolymer, silicon dioxide particles, and poly (acrylic acid). The liquid crystal polymer layer 1416 is a solid film and has a melting point of 300° C. to 350° C. and a CTE of 18 ppm/° C. to 22 ppm/° C. The manufacturing conditions and property test results of the composite substrate 1400 of Examples 9 to 16 are shown in Table 2 below. It can be seen from Table 2 below that the composite substrate 1400 of Examples 9 to 16 can have a peel strength of 1.0 kgf/cm to 1.4 kgf/cm, a dielectric constant (Dk) of 2.4 to 3.0, and a loss factor (Df) of 0.0026 to 0.0029, so they are suitable as high-frequency and high-speed substrates.

TABLE 2

| | Thickness of | Thickness of | Thickness of | | | | | | |
|---|---|---|---|---|---|---|---|---|---|
| | liquid crystal | first | second | Bonding | Heating | Peel | Dk | Df | |
| | polymer layer | fluoropolymer | fluoropolymer | temperature | time | strength | (10 | (10 | CTE |
| Example | (μm) | layer (μm) | layer (μm) | (° C.) | (minute) | (kgf/cm) | GHz) | GHz) | (ppm/° C.) |
| 9 | 25 | 12.5 | 12.5 | 300 | 60 | 1.0 | 3.0 | 0.0029 | 27 |
| 10 | 25 | 12.5 | 12.5 | 350 | 10 | 1.2 | 3.0 | 0.0029 | 27 |
| 11 | 25 | 25 | 25 | 300 | 60 | 1.3 | 2.8 | 0.0026 | 29 |
| 12 | 25 | 25 | 25 | 350 | 10 | 1.4 | 2.8 | 0.0026 | 29 |
| 13 | 50 | 12.5 | 12.5 | 300 | 60 | 1.1 | 2.6 | 0.0028 | 26 |
| 14 | 50 | 12.5 | 12.5 | 350 | 10 | 1.2 | 2.6 | 0.0028 | 26 |
| 15 | 50 | 25 | 25 | 300 | 60 | 1.3 | 2.4 | 0.0026 | 28 |
| 16 | 50 | 25 | 25 | 350 | 10 | 1.4 | 2.4 | 0.0026 | 28 |

In summary, the present disclosure provides a composite substrate and a method for manufacturing the same. The composite substrate of the present disclosure can have a low dielectric constant, a low loss factor, a low thermal expansion coefficient, a low water absorption rate, and good bonding strength. The manufacturing method of the present disclosure can manufacture the composite substrate by a simple process, which is beneficial to reducing manufacturing costs.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A composite substrate comprising:
a first fluoropolymer layer;
a liquid crystal polymer layer bonded to an upper surface of the first fluoropolymer layer;
a second fluoropolymer layer bonded to an upper surface of the liquid crystal polymer layer, wherein the first fluoropolymer layer and the second fluoropolymer layer independently comprise:
30 parts by weight to 50 parts by weight of a fluoropolymer;
1 part by weight to 5 parts by weight of a dispersant;
1 part by weight to 10 parts by weight of a plurality of inorganic particles; and
1 part by weight to 5 parts by weight of a macromolecule resin, wherein the macromolecule resin is different from the fluoropolymer.

2. The composite substrate of claim 1, wherein the fluoropolymer comprises polytetrafluoroethylene, ethylene-tetrafluoroethylene copolymer, tetrafluoroethylene-hexafluoropropene copolymer, tetrafluoroethylene-perfluoroalkyl vinyl ether copolymer, polychlorotrifluoroethylene, ethylene-trifluorochloroethylene copolymer, trifluorochloroethylene-tetrafluoroethylene copolymer, polyvinylidene difluoride, tetrafluoroethylene-hexafluoropropene-difluoroethylene copolymer, tetrafluoroethylene-perfluoroalkoxy vinyl ether copolymer, or combinations thereof.

3. The composite substrate of claim 1, wherein the inorganic particles comprise titanium dioxide, silicon dioxide, aluminum oxide, zirconium dioxide, magnesium oxide, calcium oxide, talc, aluminium hydroxide, magnesium hydroxide, barium sulfate, calcium carbonate, potassium titanate, clay, or combinations thereof.

4. The composite substrate of claim 1, wherein the dispersant comprises ethyl acetate, butyl acetate, ethylene glycol ethyl ether acetate, phthalate, propylene glycol methyl ether acetate, urethane acrylate, tripropylene glycol diacrylate, 1,6-hexanediol diacrylate, propylene glycol monomethyl ether acetate, ethylene glycol methyl ether acetate, 2-methoxyethyl acetate, ethyl acrylate, fatty acid polyethylene glycol ester, vinyl formate, methyl acrylic ester, or combinations thereof.

5. The composite substrate of claim 1, wherein the macromolecule resin comprises poly (acrylic acid), polyimide, a liquid crystal polymer, a cyclic olefin polymer, a cyclic olefin copolymer, a styrene-butadiene copolymer, a styrene-ethylene copolymer, a styrene-propylene copolymer, a styrene-butylene copolymer, a polyester, a polyolefin, polyphenylene ether, polyphenylene sulfide, styrene, polycarbonate, polyarylate, maleimide resin, polysulfone, polyarylsulfone, polyaryletherketone, epoxy resin, polyvinyl acetate, polyaryl amide, polyetheretherketone, poly (ether sulfone), polyphenylene oxide, polyoxymethylene, polyetherimide, polysiloxane, or combinations thereof.

6. A method for manufacturing a composite substrate, comprising:
stacking a first fluoropolymer layer, a liquid crystal polymer layer, and a second fluoropolymer layer in a bottom-to-top sequence, wherein the first fluoropolymer layer and the second fluoropolymer layer independently comprise:
30 parts by weight to 50 parts by weight of a fluoropolymer;
1 part by weight to 5 parts by weight of a dispersant;
1 part by weight to 10 parts by weight of a plurality of inorganic particles; and
1 part by weight to 5 parts by weight of a macromolecule resin, wherein the macromolecule resin is different from the fluoropolymer; and
performing a heating process to bond the first fluoropolymer layer, the liquid crystal polymer layer, and the second fluoropolymer layer, wherein a temperature of the heating process is 200° C. to 400° C. or a glass transition temperature of the fluoropolymer to a melting point of the fluoropolymer +40° C.

7. The method of claim 6, wherein the first fluoropolymer layer and the second fluoropolymer layer further comprise 30 parts by weight to 60 parts by weight of a solvent and respectively a dispersion liquid layer, and the liquid crystal polymer layer is a solid film or an adhesive layer.

8. The method of claim 7, wherein the solvent comprises N-methyl-2-pyrrolidone, methyl ethyl ketone, N,N-dimethylacetamide, or combinations thereof.

9. The method of claim 6, wherein the first fluoropolymer layer, the second fluoropolymer layer, and the liquid crystal polymer layer are respectively a solid film.

10. The method of claim 9, further comprising: when performing the heating process, placing the first fluoropolymer layer, the liquid crystal polymer layer, and the second fluoropolymer layer in a nitrogen gas oven or an infrared oven.

11. The method of claim 9, further comprising: when performing the heating process, performing a pressing process, wherein the pressing process has a pressure of 1 kg/cm² to 100 kg/cm².

12. The method of claim 6, wherein the heating process has a heating time of 1 minute to 300 minutes.

13. The method of claim 6, further comprising: hot-pressing the composite substrate and a metal substrate.

14. The method of claim 6, further comprising:
stacking the first fluoropolymer layer, the liquid crystal polymer layer, and the second fluoropolymer layer in the bottom-to-top sequence on a metal substrate; and
performing the heating process to bond the first fluoropolymer layer and the metal substrate.

15. The method of claim 6, further comprising:
before stacking the first fluoropolymer layer, the liquid crystal polymer layer, and the second fluoropolymer layer in the bottom-to-top sequence;
coating a first liquid crystal polymer adhesive layer to cover an upper surface of the first fluoropolymer layer;
coating a second liquid crystal polymer adhesive layer to cover a lower surface of the second fluoropolymer layer; and
curing the first liquid crystal polymer adhesive layer and the second liquid crystal polymer adhesive layer to respectively form a first portion and a second portion of the liquid crystal polymer layer.

16. The method of claim 6, further comprising:
before stacking the first fluoropolymer layer, the liquid crystal polymer layer, and the second fluoropolymer layer in the bottom-to-top sequence,
coating a liquid crystal polymer adhesive layer to cover a lower surface of the second fluoropolymer layer; and
curing the liquid crystal polymer adhesive layer to form the liquid crystal polymer layer.
